(19) United States
(12) Patent Application Publication
(10) Pub. No.: US 2016/0351802 A1
(43) Pub. Date: Dec. 1, 2016

(54) NONLINEAR DIELECTRIC STACK CIRCUIT ELEMENT

(71) Applicant: HEWLETT PACKARD ENTERPRISE DEVELOPMENT LP, Houston, TX (US)

(72) Inventors: Warren Jackson, San Francisco, CA (US); Gary Gibson, Palo Alto, CA (US); R. Stanley Williams, Palo Alto, CA (US); Jianhua Yang, Palo Alto, CA (US)

(21) Appl. No.: 15/111,515

(22) PCT Filed: Jan. 30, 2014
(86) PCT No.: PCT/US2014/013957

§ 371 Date: Jul. 14, 2016

(51) Int. Cl. H01L 45/00; G11C 13/00

(52) U.S. Cl. CPC H01L 45/12; G11C 13/003

(57) ABSTRACT

A nonlinear dielectric stack circuit element includes a first layer of material having a first dielectric constant; a second layer of material having a second dielectric constant; and a third layer of material sandwiched between the first layer of material and the second layer of material and having a third dielectric constant. The third dielectric constant has a value less than the first dielectric constant and the second dielectric constant.

### BACKGROUND

Memory structures such as DRAM and ReRAM find increasingly imported applications in modern compulsion and communication, as do related components, such as memristors and neuristors, and other structures, such as amplifiers, oscillators, mixers, antennas and the like. As the use of digital data increases, the demand for faster, smaller, and more efficient operation of such structures increases, particularly in regard to memory structures. One type of memory structure that has recently been developed is a crossbar memory array. A crossbar memory array includes a set of upper parallel wires that intersect a set of lower parallel wires. A crossbar array having n upper wires and m tower wires generally provides n*m interconnections connecting the upper set of wires to the lower set of wires. A programmable element configured to store digital data may be placed at each intersection of the wires.

### BRIEF DESCRIPTION Of THE DRAWINGS

The accompanying drawings illustrate various examples of the principles described herein and are a part of the specification. The illustrated examples are merely examples and do not limit the scope of the claims.

FIG. 1 is a diagram showing an illustrative crossbar array, according to one example of the principles described herein.

FIG. 2 is a diagram illustrating a selector element positioned adjacent a memristive element, according to one example of the principles described herein.

FIGS. 3A-3B are diagrams showing an illustrative section of a crossbar array with select voltages applied, according to one example of the principles described herein.

FIG. 4 is a diagram showing an illustrative nonlinear dielectric stack selector device according to one example of the principles described herein.

FIG. 5 is a potential band diagram far an illustrative nonlinear dielectric slack selector device according to one example of the principles described herein.

FIG. 6 is a current density diagram for an illustrative nonlinear dielectric stack selector device according to one example of the principles described herein.

FIG. 7 is a flowchart showing an illustrative method for fabricating a crossbar array using illustrative nonlinear dielectric stack selector devices according to one example of the principles described herein.

Throughout the drawings, identical reference numbers designate similar, but not necessarily identical, elements.

### DETAILED DESCRIPTION

Crossbar arrays find applications in many areas of modern computing and communication, including, for example, in communication networks and FPGAs. A memory array utilizing crossbar architectures is subject to a number of design constraints. One of these constraints limits the number of programmable elements that can be placed along a particular wire within the memory array. The number of programmable elements is constrained because having too many programmable elements along a particular wire makes it more difficult to isolate a particular programmable element for reading and writing operations.

For example, particular programmable elements within a cross bar array are often read from or written to by applying half a read or write voltage to one wire connected to the target programmable element and the other half read or write voltage to the other wire connected to the target programmable element. This arrangement applies a full read or write voltage to the target programmable element while applying only half of the mad or write voltage to the remaining, or half-selected, programmable elements. The half-selected programmable elements are these programmable elements positioned along the same upper and lower lines (or row and column lines) as a fully selected target programmable element. When half the mad or write voltage is applied to the half-selected programmable elements, currents are produced that add to the current sensed, for example, by the reading circuitry used to sense the electric current from the target programmable element; a fraction of the currents used to write also pass through half-selected write elements. These additional currents can adversely impact the read, write and erase processes. For example, the currents can cause a misread of the state of a target programmable element and can cause inadvertent writing during the course of many reads, sometimes referred to as “read disturb.”

Each half-selected programmable element contributes a small amount of unwanted current (sometimes referred to as a “sneak current”) to sensing or writing circuitry used to sense or write with the current flowing through the target programmable element. To limit the amount of electric current contributed by the half-selected programmable elements, non-linear selecting devices or selectors may be used. Selectors of the type described herein facilitate programmable elements having high-degrees of nonlinearity. Programmable elements having high degrees of nonlinearity allow a memory array to have greater numbers of programmable elements along a particular line. For example, where sneak currents are otherwise on the order of the signal current, a nonlinearity limiting the sneak current to 1/1000^{th} of the current at one-half the read or write voltage permits upward of about 1,000 programmable elements along a particular upper or lower line.

The disclosure provided herein describes a highly nonlinear selector, generally useful in any two-terminal device or array of such devices. Selectors may generally be used to “select” a desired device over others in, for example, an array of two-terminal devices. Thus, while selectors are useful in crossbar memory architectures, they are also useful in other applications, such as temperature, pressure or optical sensing. In general, selectors of the type disclosed herein are useful in any two-terminal device where the current flowing through the device or the resistance of the device is to be determined or controlled. While the disclosure herein often describes the construction, operation and use of nonlinear selectors with application to computer architectures, it should be understood that such selectors are useful in other applications as well. Accordingly, the description that follows should be understood to encompass the construction, operation and use of selectors in two-terminal devices, generally, and not be limited to use in computer architectures or crossbar arrays.

As mentioned above, particular programmable elements within a crossbar array are often read from or written to by applying half the read or write voltage to one wire connected to the target programmable element end the other half read or write voltage to the other wire connected to the target programmable element. This arrangement applies the full read or write voltage to the target programmable element while only applying half of the read or write voltage to the half-selected programmable elements. When half the read or write voltage is applied to the half-selected programmable elements, a current is produced that adds to the current sensed by the reading or writing circuitry used to sense the electric current flowing through the target programmable element. Each half-selected programmable element contributes a small amount of unwanted current (sometimes referred to as “sneak current”) to sensing circuitry used to sense the current flowing through the target programmable element. To limit the amount of electric current contributed by the half-selected programmable elements, non-linear devices may be used. As stated previously, it is generally desirable to use programmable elements exhibiting a high degree of non-linearity. Without limiting the disclosure herein, non-linearity of programmable elements may be achieved by incorporating a selector into the programmable element. For example, a selector or selector device may be connected in series with a memristive element to form a programmable element. The resulting nonlinearity of the programmable element arises primarily from the nonlinearity of the selector.

In light of this and other issues, the present specification discloses a dielectric stack circuit device or selector, obtained by sandwiching a low dielectric material between layers of high dielectric material. The present specification further discloses the use of such circuit devices, for example, as selectors in crossbar memory structures that use programmable elements positioned between the upper and lower lines of the crossbar array. The dielectric slack circuit devices or selectors disclosed herein, when used in series with a relatively linear memory device, can provide a high overall nonlinearity for the programmable element, defined generally as K=I(V)/I(V/2), where I is the device current, V is the voltage across the programmable element (i.e., across the memory device+selector) and V/2 is the half-select voltage. When used in memory structures such as crossbar memory structures, the dielectric circuit devices or selectors substantially reduce current contributions (or sneak currents) arising from half-selected programmable elements. Further details on the construction and application of the circuit devices or selectors disclosed herein and the nonlinearity of the devices is provided below. While the following disclosure is directed primarily to dielectric circuit devices, or selectors based on such devices and their use in crossbar arrays, it should be understood that the dielectric circuit devices described herein are applicable to many other applications where high degrees of nonlinearity at nanoscale dimensions are desired.

In one example of the principles disclosed herein, a nonlinear dielectric stack circuit element includes: a first layer of material having a first dielectric constant; a second layer of material having a second dielectric constant; and a third layer of material sandwiched between the first layer of material and the second layer of material and having a third dielectric constant. The third dielectric constant has a value less than the first dielectric constant and the second dielectric constant.

In another example, a nonlinear selector circuit element includes: an injector layer of material having a first dielectric constant; a shutter layer of material having a second dielectric constant; and a hinge layer of material sandwiched between the injector layer of material and the shutter layer of material and having a third dielectric constant. The third dielectric constant has a value less than the first dielectric constant and the second dielectric constant.

In another example, a method of accessing a target element within an array includes: applying half of an access voltage to row line connected to said target element, said target element comprising a dielectric stack circuit; applying an inverted half of said access voltage to a column line connected to said target element; and detecting the electric current flowing through said target element to determine a state of said target element.

Through use of the apparatus, methods and systems described herein, highly nonlinear dielectric circuit devices, or crossbar arrays, for example, utilizing highly nonlinear selectors in programmable elements, can be realized. In the example of crossbar arrays, the use of highly nonlinear selectors to create highly nonlinear programmable elements within the crossbar array increases the number of programmable elements that can be placed along a particular row line or column line of the crossbar array. This allows for greater block sizes and thus mom efficient memory structures and also allows for reduced cost and power consumption. As stated above, while the description of the relevant principles is provided in the context of selectors used in programmable elements and crossbar arrays, the same principles are generally applicable to any two-terminal device or array of such devices where the current flowing through the device or the resistance of the device is to be determined or controlled. Accordingly, the description that follows should be understood to encompass the construction, operation and use of selectors in two-terminal devices, generally, and not be limited to use in computer architectures or crossbar arrays.

In the following description, for purposes of explanation, numerous specific details are set forth in order to provide a thorough understanding of the present apparatus, systems and methods. It will be apparent, however, to one skilled in the art that the present apparatus, systems and methods may be practiced without these specific details. Reference in the specification to “an example” or similar language means that a particular feature, structure, or characteristic described in connection with the example is included in at least that one example, but not necessarily in other examples.

Throughout the remainder of this specification and in the appended claims, and unless otherwise specified, the terms “access voltage,” “read voltage” and “write voltage,” as well as the term “voltage” in general, are used to refer to the voltage drop across a programmable element as opposed to the voltages applied to the ends of the row and column lines that connect to the programmable element. The description within this specification will describe operations primarily in terms of read or select voltages. However, it will be apparent to those skilled in the art that the principles described herein can apply to write and erase voltages as well, in addition to non-memory based applications.

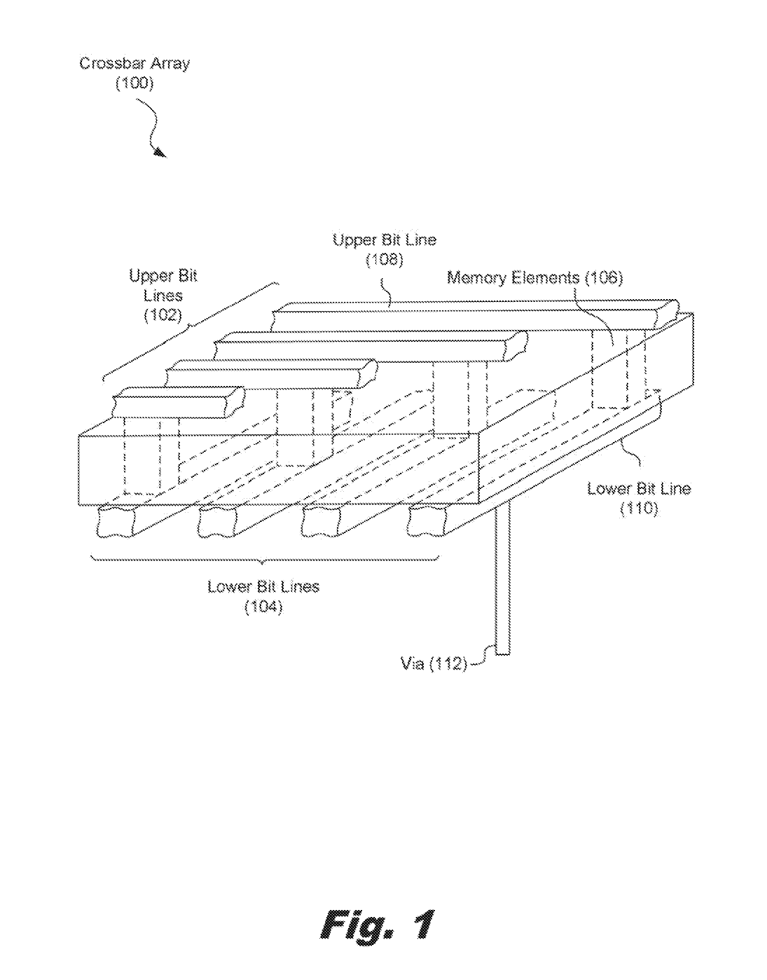

Referring now to the figures, FIG. 1 is a diagram showing an illustrative crossbar memory array architecture (100). According to certain illustrative examples, the crossbar memory array (100) may include an upper set of lines (102) which may generally be In parallel. Additionally, a lower set of lines (104) is generally perpendicular to, and intersects, the upper lines (102). The upper lines and the lower lines may be referred to as word lines or bit lines depending on how data is written to or read from the memory array (100).

Programmable crosspoint elements (106) are formed at the intersections between an upper line (108) and a lower line (110). For purposes of illustration, the upper set of parallel lines will sometimes be referred to as row lines and the lower set of parallel lines will sometimes be referred to as column lines. Terms such as row, column, upper, and lower are not used to indicate a specific position or orientation. Rather, the terms are used to distinguish position or orientation relative to one another.

According to certain illustrative examples, the programmable crosspoint elements (106) may be memristive devices, having a selector in series with a programmable element, such as a memristor. In one example, the selector and programmable element may be fused together without an intervening layer—e.g., electrode—to comprise a composite device. Memristive devices exhibit a “memory” of past electrical conditions. For example, a memristive device may include a matrix material that contains mobile dopants. These dopants can be moved within a matrix to dynamically alter the electrical operation of an electrical device, such as the resistance of that device.

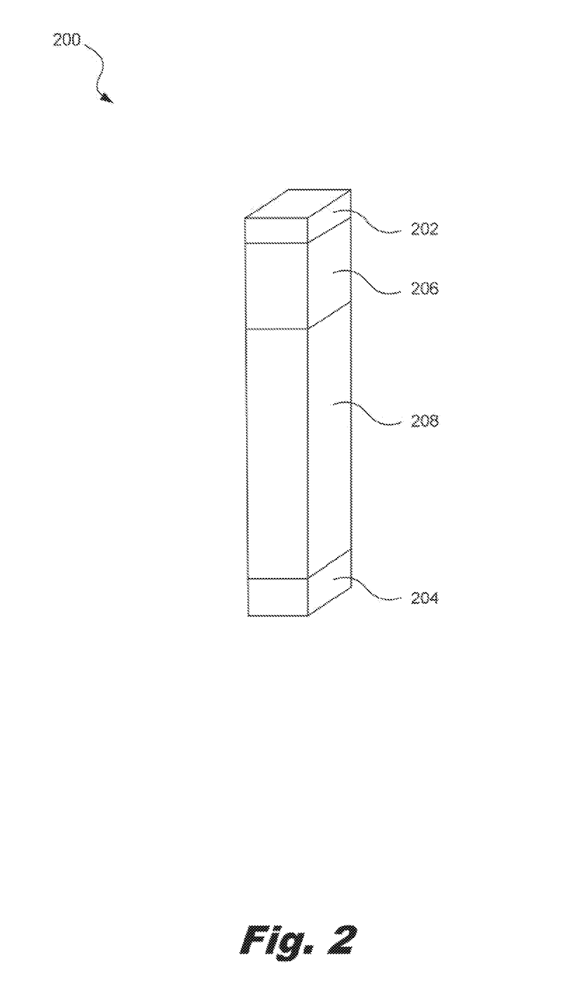

FIG. 2 illustrates one example of a programmable element (108) suitable for use In a crossbar memory array (100). A memristive memory device (200) includes a first electrode (202) and a second electrode (204), sandwiching a selector (206) and a memory device, such as a memristive device or memristor (208). The memristor (208) may be a thin film (generally less than 20 nm thick) and, in many cases, is nanocrystalline or amorphous. The mobility of the dopant species in such nanostructured materials is much higher than in a bulk crystalline material, since diffusion can occur through grain boundaries, pores, or through local structural imperfections in an amorphous material. Also, because the film is so thin, the amount of time needed to drift enough dopants into or out of a local region of the film to substantially change its conductivity, and, hence, its state, is relatively rapid. Another advantage of nanometer scale memristive devices is that a large electrical field can be produced by a relatively small applied voltage across the device. The memristor (208) is sometimes referred to as a switch, in that the memristor may assume an “OFF” state, where little to no conductance for electric current occurs, and an “ON” state, where increased conductance for current occurs.

As discussed in further detail below, the programmable element (106) includes a selector (206). The selector (206) generally exhibits a highly nonlinear current-voyage response over a range of voltages, typically both positive and negative. Depending on the application, the nonlinearity of the selector (206) serves to block or substantially reduce current at sub-threshold voltages. For example, the selector (206) may serve to block or substantially reduce current to the memristive device or memristor (208) at voltages less than the full read or write voltages referred to above. In one example, the selector exhibits a non-linearity such that the current flowing through the selector at the half-voltage (write or read) is much less than the current at the corresponding full voltage. Stated mathematically, the nonlinearity, K, of the programmable element is expressed as K=I(V)/I(V/2)>>2, where V is the voltage drop across the programmable element and K=2 is the value expected for an essentially linear device. In the discussion below, details of a selector based on a dielectric circuit device and its use in memory systems, such as crossbar memory arrays having memristive memory devices, are provided. While the discussion provides examples of the selectors being used with memresistive memory devices, one skilled in the art will appreciate that the selectors disclosed herein can be used in other memory systems, such as, for example, those based on phase change memory devices.

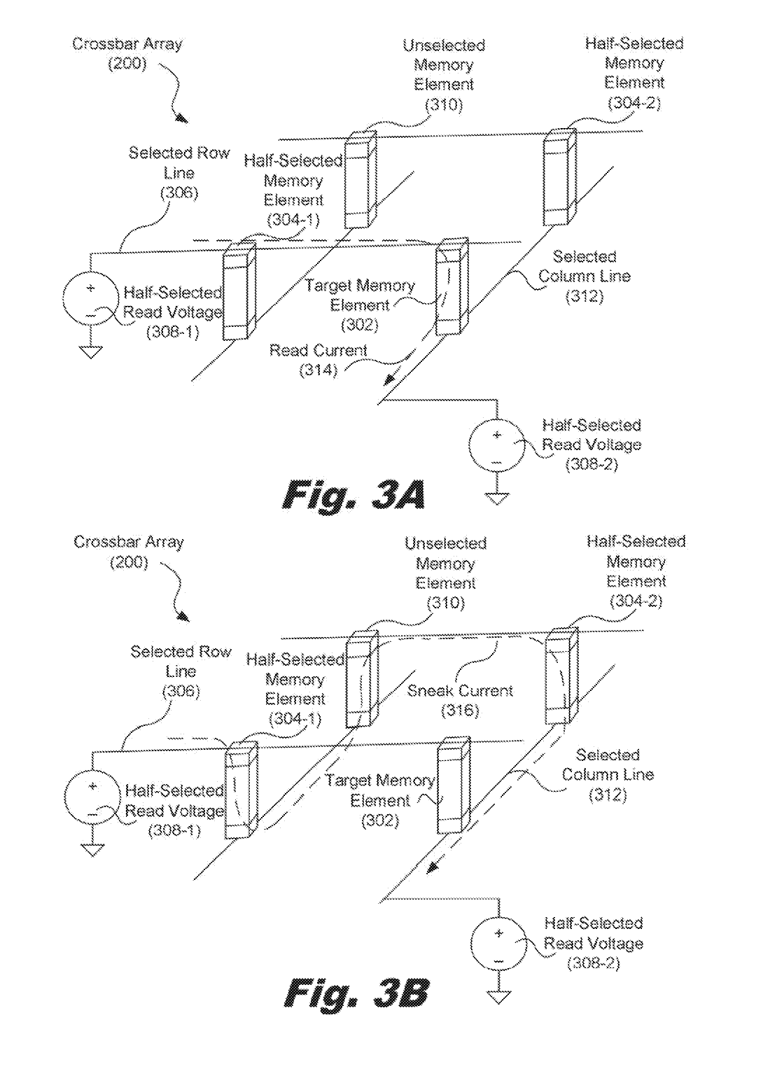

FIGS. 3A-3B are diagrams showing an illustrative section of a crossbar array. As mentioned above, a crossbar array may be formed by placing programmable elements at intersections between row lines and column lines. To access a particular programmable element, a select voltage is applied across that element. The programmable element to be accessed will be referred to as the target programmable element (302). The following will describe an example of how to access the target programmable element (302) for a reading operation.

To read the state of the target programmable element (302), a half-select read voltage (308-1) is applied to the row line (306) connected to the target programmable element (302) (voltage drops across the row and column lines are assumed negligible for purposes of this discussion). This row line will be referred to as the selected row line (306). With the hail-select read voltage applied, each programmable element (304-1) along the selected row line (306), including the target programmable element (302), becomes half selected (assuming the undetected lines are grounded). To fully select the target programmable element (302), a half-select read voltage (308-2), of the opposite polarity of that applied to the selected row line (306), is applied to the column line connected to the target programmable element (302). This column line will be referred to as the selected column line (312). With the half-select read voltage (308-2) applied to the selected column line (312), the programmable elements (304-2) along the selected column line will become half selected (assuming the unselected lines are grounded), except for the target programmable element (302) which becomes fully selected. The half-select read voltage (308-2) applied to the column line (312) may be the inverse polarity of the half-select read voltage (308-1) applied to the selected row line (308). This will cause the voltage drop across the target programmable element (302) to be the sum of both half-select read voltages (308-1, 308-2). Alternatively, the read voltage (308-1) applied to the row line (300) can be the full voltage, while the read voltage (308-2) applied to the column line (312) can be held at ground; other combinations of select voltages resulting in a full select voltage drop across the target programmable element are readily apparent. The unselected row lines and the unselected column lines may be grounded, set at a nonzero fixed voltage or left floating. The manner in which unselected lines are handled may depend on the design of the system.

With the full select voltage applied across the target programmable element (302), a read current (314) flows through the selected row line (306), the target programmable element (302), and the selected column line (312). The value of the read current will be indicative of the state of the target programmable element (302)—i.e., whether the state is “ON” or “OFF.” Thus, sensing circuitry can be used to measure the read current and determine whether the target programmable element is storing a digital ‘1’ or a digital ‘0’. Multi-bit reading or recording may also be performed using the circuitry described.

As mentioned above, when applying half-select read voltages to the row lines and column lines, programmable elements (304-1 , 304-2) along those lines become halt selected; or, approximately half selected if the unselected lines are left floating. This causes an electric current, sometimes called a sneak current, to flow through these programmable elements (304) as well. FIG. 3B illustrates a possible path of a sneak current (316). The value of the sneak current (316) is dependent on the current to voltage relationship of the programmable elements. Using programmable elements whose current increases super-linearly with voltage substantially reduces the value of the electric current contributed by each of the half-selected programmable elements (304) or other unselected devices.

For example, if the selectors used in the programmable elements have a relatively small non-linearity in the current to voltage relationship, then the ratio between currant flowing through a programmable element with the full voltage applied end the current flowing through a programmable element with the half voltage applied is relatively small, and equals K=2 for substantially linear behavior. This will cause the half-selected programmable elements (304) as well as other unselected programmable elements (310) to contribute a relatively large amount of current to the sneak current (316). Conversely, if the selectors used in the programmable elements have a high degree of non-linearity, then the ratio between current flowing through a programmable element with the full voltage applied and the current flowing through a programmable element with the half voltage applied is relatively large. This will cause each half-selected programmable element (304) to contribute a relatively small amount to the sneak current (316). This allows more programmable elements to be placed along a particular line without creating too large of a sneak current (316). A large sneak current (316) will interfere with the read current (314) and make it difficult for the sensing circuitry to accurately determine the state of the target programmable element (302).

In light of this issue, the present specification discloses a circuit device or element, sometimes referred to as a selector, with a high degree of nonlinearity that can be used in conjunction with relatively linear elements to enable their use in large crossbar arrays or other systems. Particularly, a highly nonlinear selector includes a dielectric stack, obtained by sandwiching a low dielectric layer between two layers of high dielectric material. In general, and without limiting the disclosure herein, the dielectric stack includes a first layer of material having a relatively high dielectric constant, referred to herein as an injector layer. Adjacent the injector layer is a second layer of material having a relatively low dielectric constant, referred to herein as a hinge layer. Adjacent the hinge layer is a third layer of material having a relatively high dielectric constant, referred to herein as a shutter layer. The arrangement of materials having relatively low and high dielectric constants, in the presence of a voltage bias across the stack, provides a barrier to current flow (high electrical resistivity) when the potential energy of the shutter layer at its interface with the electrode exceeds the potential energy of the injector layer at its interface with the electrode. This occurs through blocking of quantum mechanical tunneling of charge carriers across the combined layers of the device. Conversely, when the potential energy of the shutter layer drops below the potential energy of the injector layer, the stack permits current to flow (low electrical resistivity), which occurs as a result of tunneling through the injector layer.

In addition to the properties of the differing dielectrics, the band offset and thicknesses are engineered for proper function of the device. The current through the injector layer meets the needed on-current, so if the band offset is large, the thickness is thin, while if the band offset is small, the injector layer can be thicker. Typically, if the band offset is 1 eV, the injector layer may be 1-2 nm thick for current densities of 10⁴ A/cm². The shutter layer is sufficiently blocking to impede the current flowing through the device at low voltages. Thicker shutter layers are desirable up to the point where the bulk resistance dominates over the tunnel resistance through the Injector layer. Hence, for optimal selecting for one bias direction, a thin, small band offset injector and a thick, large band offset shutter, are needed. However, if symmetric electrical characteristics are needed, an intermediate thickness and band offset are needed. As illustrated below, the electrical characteristics of the stack provide for a high degree of nonlinearity.

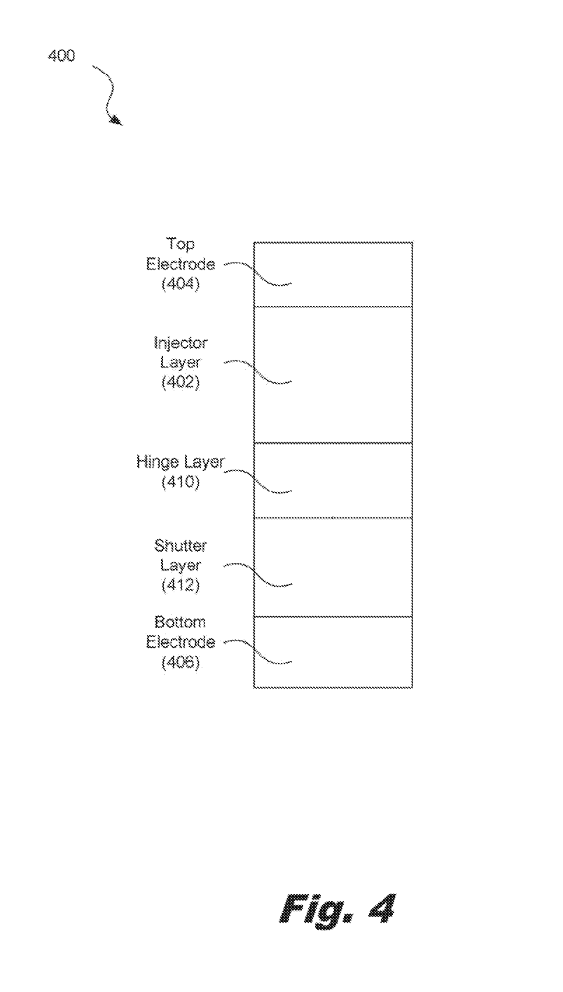

FIG. 4 is a diagram showing an illustrative dielectric stack circuit device or selector (400) according to the principals disclosed herein. According to certain illustrative examples, the selector element includes an injector layer (402) in series with a hinge layer (410) and a shutter layer (412). The injector layer (402) and the shutter layer (412) are placed between a top electrode (404) and a bottom electrode (408), It will be appreciated by those skilled in the art that the electrodes may or may not be needed, depending on the application. For example, when the dielectric stack is used as a selector in conjunction with a memristive or phase change memory device, one or both of the electrodes may be eliminated, particularly at the interface between the memristive or phase change device and the selector device.

Examples of materials that have suitable dielectric properties are Ta₂O₅, having a dielectric constant of about 23-25, and CsCu₃Ti₄O₁₂, having a very large dielectric constant greater than 100 and a band gap of about 1.5 eV. TaNx (1<x<2) and Ta₃N₅ are other materials exhibiting the desired properties.

Materials exhibiting low dielectric constants and low band gaps are more difficult to identify because lower band gaps tend to yield high dielectric constants. Examples of materials having the desired properties include SiC, which has a dielectric constant of about 9.72 and a relatively small band gap of about 2.4 eV for 3C phase, about 3.0 eV tor 6H phase, and about 3.2 eV for 4H phase. SiCO is a similar material having suitable dielectric constant and band gap. SiN is also a possible material having a band gap of about 5 eV and a dielectric constant of about 5.8. Generally, a wide band gap material with a low dielectric can have its effective band gap decreased by the suitable introduction of defects or impurities. Thus, a number of high band gap materials could be made suitable through introduction of sufficient dopants, impurities and/or trap densities to create defect or impurity conduction bands. For example, silicon rich SiO₂ is such a wide band gap material exhibiting the desired properties of tow dielectric constant with purity band conduction Ge could also be added to SiC to provide conduction paths through the barrier without changing the dielectric constant.

Materials suitable for the electrodes (404) and (406) can be composed of, for example, titanium (Ti), platinum (Pt), gold (Au), copper (Cu), tungsten (W), combinations thereof, such as TiW, or any other suitable metal, metallic compound (e.g. some perovskites with or without dopants such as BaTiO₃ and Ba₁₋ₓLaₓTiO₃, PrCaMnO₃) or semiconductor. The electrodes (404) and (406) can also be composed of metallic oxides or nitrides, such as RuO₂, IrO₂, TaN and TiN. The electrodes (404) and (406) can also be composed of any suitable combination of these materials. For example, in certain examples, the top electrode (404) can be composed of Pt and the bottom electrode (408) can be composed Au. In other examples, the top electrode (404) can be composed of Cu, and the bottom electrode (406) can be composed of IrO₂. In still other examples, the top electrode (404) can be composed of a suitable semiconductor, and the bottom electrode (406) can be composed of Pt.

In one example, the top electrode (404) comprises TiN and the bottom electrode (406) comprises TiW. The injector layer (402) comprises a high dielectric Ta₂O₅ material. The band gap offset between the top electrode (404) and the injector layer (402) is about 0.8-1.0 eV and controls the high current ON state of the device. Larger barriers result in higher electrical resistances and greater temperature dependencies unless the barriers are sufficiently thin to permit tunneling. The band offset of the injector layer can be used to adjust the electrical resistance to match the programmable element. For example, an electrical resistance of between 1 and 10 MΩ is desirable in various examples, which translates into a band offset of about 0.9 eV. Injector layers exhibiting low band gap offsets or thin band gaps permit high currents for the ON state of the device and high current-voltage nonlinearities.

In one example, the hinge layer (410) comprises SiN, which is a low dielectric material, having a band offset about equal to or slightly less than that of the injector layer (402). In various examples, the hinge layer exhibits a dielectric constant of about 4 or less and the ability to withstand electric fields on the order of several MV/cm. In such examples, a band offset in the range of about 1 eV or less is desirable.

In one example, the shutter layer (412) comprises Ta₂O₅, which is a high dielectric material having a low band gap. The shutter layer may, alternatively, comprise the same material used in the injector layer (402). A high dielectric constant at the shutter layer (412), relative to that of the hinge layer (410), facilitates a substantial voltage drop across the hinge layer (410). Additionally, the shutter layer (412) should have a thickness that limits tunneling when the device is in the low current OFF state and a band offset about the same as the injector layer (402) and hinge layer (410). In such examples, a band offset in the range of about 0.9-1.0 eV is desirable. Observations with some examples indicate that where the shutter layer band offset is X eV, the maximum nonlinearity, K, peaks at about X volts, provided there is small voltage drop across the injector layer relative to the voltage drop across the device.

In one example, a symmetric dielectric stack device or selector is provided. For example, a symmetric dielectric stack device or selector includes a top electrode (404) comprising Ta and a bottom electrode (406) comprising Ta. The injector layer (402) comprises Ta₂O₅, which exhibits a dielectric constant of about 23-25 and a band gap of about 4.4 eV. In other cases, the injector layer (402) may comprises TiO₂, which exhibits a dielectric constant of about 60 and a band gap of about 3.0 eV. The injector layer is about 2 nm thick and has a cross sectional area about 900 nm². The hinge layer (410) comprises SiN, which exhibits a dielectric constant of about 5.8 and a band gap of about 5 eV. The hinge layer is about 2 nm thick and has a cross sectional area about 900 nm². The shutter layer (402) comprises Ta₂O₅, which exhibits a dielectric constant of about 23-25 and a band gap of about 4.4 eV. The injector layer is about 2 nm thick and has a cross sectional area about 900 nm².

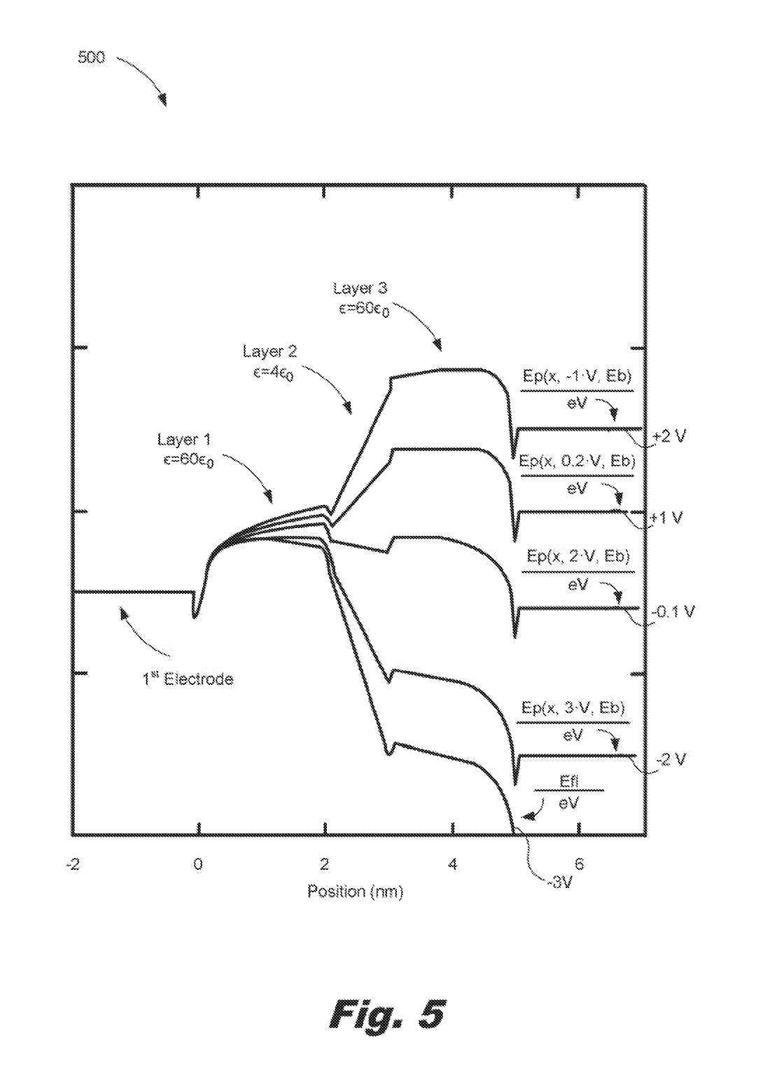

FIG. 5 provides a potential band diagram for me exemplar symmetric dielectric stack device or selector described above. The values for potential include the image charge potential and the effect of various applied biases referenced to the 1^{st} or top electrode (404). Under negative bias with respect to the 1^{st} or top electrode (404), the electrons travel from right to left in the diagram. Similarly, under positive bias., the electrons travel from left to right. As the bias becomes increasingly negative—e.g., going from −0.1 to −2.0 V in the diagram—the potential of the shutter layer (Layer 3) drops below the potential of the 1^{st} or top electrode (404) and the electron flow increases rapidly.

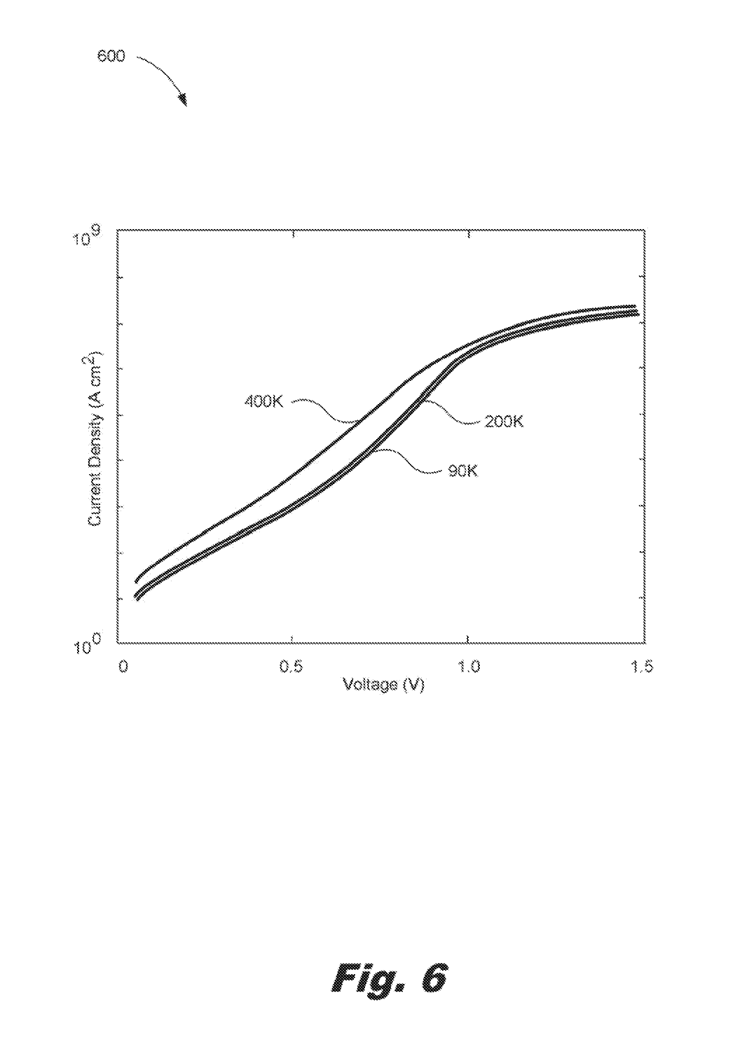

FIG. 6 provides the expected current density (calculated using a WKB approximation) for the exemplar symmetric device described above and referenced in FIG. 5. As is apparent from the data, the nonlinearity of the device, defined as K=I(V)/I(V/2), is in the range of greater than 1000 for V=1 Volt. Data obtained specifically for T=330 Kelvin and V=1 Volt indicate the nonlinearity K=1534. As also indicated by FIG. 8, the current density is nearly independent of temperature, particularly for values greater than 1 Volt. The ON current density at about 1 Volt is also in the range appropriate for 10-30 nm steed devices.

FIGS. 5 and 6 provide data for the symmetric exemplar device described above. As indicated, nonlinearities in the range of K=1534 for T=330 K and V=1 Volt were obtained, in alternative devices, where the electrical characteristics need not be symmetric, much higher nonlinearities have been obtained. For example, it is observed that once the bias is such that the shutter layer potential approaches that of the 1^{st} electrode, very large currents flow and the nonlinearity, K, can approach 2×10⁵ at T=330 K and V=1 Volt. This or similar structures may be acceptable in ReRAM applications where half-select currents typically Involve at least one forward and one reverse biased device, so the contributions of the unselected devices would be suppressed.

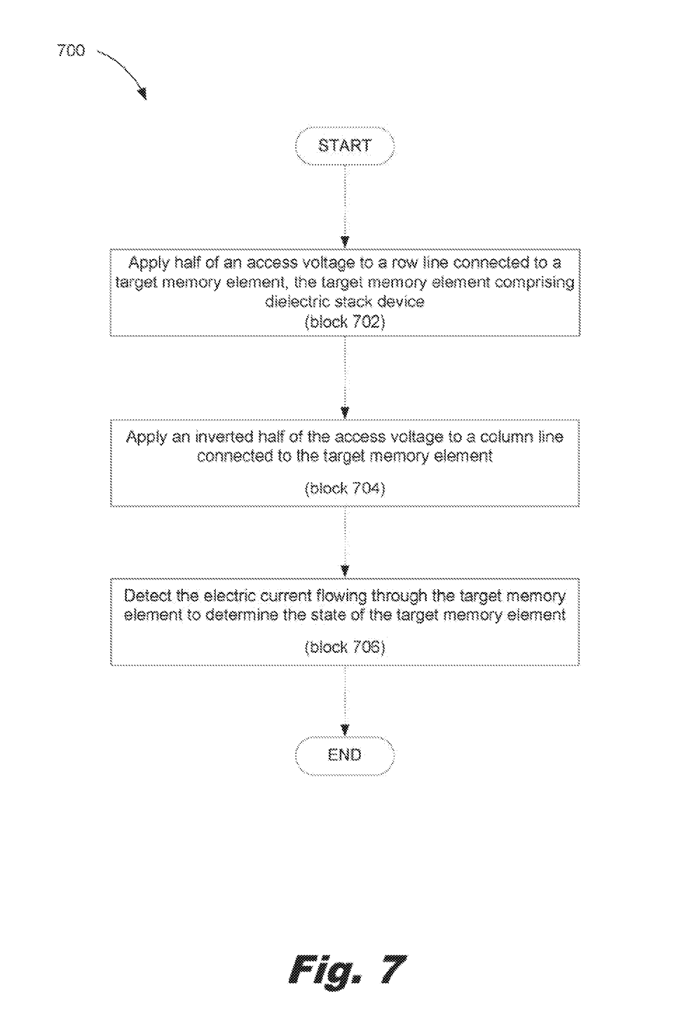

FIG. 7 is a flowchart showing an illustrative method for electrically operating (e.g., reading or writing) a crossbar array with dielectric stack devices or selectors. According to certain illustrative examples, the method includes applying (block 702) half of art access voltage to a row line connected to a target programmable element, the target programmable element comprising a dielectric, stack device or selector; simultaneously applying (704) an inverted half of the access voltage to a column line connected to the target programmable element; and for reading operation, detecting (block 706) the electric current flowing through the target programmable element to determine the state of the target programmable element.

The devices described above should incorporate well within existing technologies. Further, such devices should not require complex band gap engineering; rather, the devices can be engineered based primarily on bulk dielectric values, material determined band offsets and technologically feasible thickness dimensions on the order of about 0.5 to 10 nm.

Through use of methods and systems described herein, a nonlinear dielectric stack device or selector and a crossbar array utilizing highly nonlinear programmable elements cars be realized. This high nonlinearity of the device and the programmable elements within the crossbar array increases the number of programmable elements which can be placed along a particular row line or column line. This allows for greater block sizes and thus more efficient memory structures.

The preceding description has been presented only to illustrate and describe examples and examples of the principles described. This description is not intended to be exhaustive or to limit these principles to any precise form disclosed. Many modifications and variations are possible in light of the above teaching.

What is claimed is:

1. A nonlinear dielectric slack circuit element comprising:
a first layer of material having a first dielectric constant;
a second layer of material having a second dielectric constant; and
a third layer of material sandwiched between the first layer of material and the second layer of material and having a third dielectric constant, the third dielectric constant having a value less than the first dielectric constant and the second dielectric constant.

2. The circuit element of claim 1, wherein the first layer of material Is comprised of a material selected from the group consisting of Ta₂O₅, CaCu₃Ti₄O₁₂, TaNx (1<x<2) and Ta₃N₅.

3. The circuit element of claim 1, wherein both the first layer of material and the second layer of material are comprised of TiO₂.

4. The circuit element of claim 1, wherein the third layer of material is comprised of SiC or SiCO.

5. The circuit element of claim 1, wherein the electrical characteristics of the first, second and third layers of materials are symmetric.

6. The circuit element of claim 1, wherein the thickness and composition of the first layer allow a desired current at an applied access voltage while the thickness and composition of the second layer substantially blocks current at an applied voltage less than or about equal to one-half the applied access voltage.

7. The circuit element of claim 1, wherein the first and second dielectric constants are at least about ten times as large as the third dielectric constant.

8. The circuit element of claim 1, wherein the first and second dielectric constants are at least about twenty times as large as the third dielectric constant.

9. A nonlinear selector circuit element, comprising:
an injector layer of material having a first dielectric constant:
a shutter layer of material having a second dielectric constant; and
a hinge layer of material sandwiched between the injector layer of material and the shutter layer of material and having a third dielectric constant, the third dielectric constant having a value less than the first dielectric constant and the second dielectric constant.

10. The nonlinear selector circuit element of claim wherein both the injector layer of material and the shutter layer of material are comprised of substantially TiO₂ and the hinge layer of material is comprised of SiC or SiCO.

11. A crossbar array having the nonlinear selector element of claim 9, the crossbar array comprising:
a set of row lines intersecting a set of column lines; and
an electrical circuit element disposed at an intersection between one of the row lines and one of the column lines, in which the electrical circuit element comprises:
the injector layer of material;
the shutter layer of material; and
the hinge layer of material sandwiched between the injector layer of material and the shutter layer of material.

12. The crossbar array of claim 11, wherein the first and second dielectric constants are at least about ten times as large as the third dielectric constant.

13. The crossbar array of claim 11, wherein the first layer of material and the second layer of material am comprised of a material selected from the group consisting of Ta₂O₅, CaCu₃Ti₄O₁₂, TaNx (1<x<2) and Ta₃N₅.

14. A method of accessing a target element within an array, the method comprising:
applying half of an access voltage to a row line connected to said target element, said target element comprising a dielectric stack circuit;
applying an inverted half of said access voltage to a column line connected to said target element; and
detecting the electric current flowing through said target element to determine a state of said target element.

15. The method of claim 14, wherein the dielectric stack circuit comprises:
an injector layer of material having a first dielectric constant;
a shutter layer of material having a second dielectric constant, and
a hinge layer of material sandwiched between the injector layer of material and the shutter layer of material and having a third dielectric constant, the third dielectric constant having a value about 10 times less than the first dielectric constant and the second dielectric constant.
